(19) United States
(12) Patent Application Publication
(10) Pub. No.: US 2006/0139989 A1
(43) Pub. Date: Jun. 29, 2006

(54) Integration of 1T1R CBRAM memory cells

(75) Inventors: Ulrike Gruning Von Schwerin, Munchen (DE); Thomas Happ, Tarrytown, NY (US); Cay-Uwe Pinnow, Munchen (DE); Thomas Rohr, Aschheim (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/311,435

(22) Filed: Dec. 20, 2005

(30) Foreign Application Priority Data
Dec. 21, 2004 (DE) 10 2004 061 548.9

(51) Int. Cl. G11C 11/00

(52) U.S. Cl. 365/153

(57) ABSTRACT

A memory cell field with an integrated arrangement of solid body electrolyte memory cells, and in particular of CBRAM solid body electrolyte memory cells with 1T1R architecture, wherein the solid body electrolyte memory cells each comprise a layer stack that comprises at least a bottom and a top electroconductive, in particular metal layer and a layer of solid body electrolyte material or ion conductor material, respectively, positioned therebetween, and wherein each solid body electrolyte memory cell can be controlled via a word line, a bit line, and a plate line by means of a selection transistor, wherein at least a number of solid body electrolyte memory cells in the memory cell field have a common plate electrode or are connected to a common plate line, respectively.

### CLAIM FOR PRIORITY

This application claims the benefit of priority to German Application No. 10 2004 061 548.9, filed in the German language on Dec. 21, 2004, the contents of which are hereby incorporated by reference.

### TECHNICAL FIELD OF THE INVENTION

The invention relates to a memory cell array or a memory cell field, respectively, for the integration of resistively switching solid body electrolyte memory cells. The invention further relates to a method for manufacturing a memory cell field with an integrated arrangement of solid body electrolyte memory cells, and in particular of 1T1R CBRAM memory cells in minimum structure size.

### BACKGROUND OF THE INVENTION

An integrated memory device usually comprises a cell field (array) consisting of a plurality of memory cells and a matrix of electroconductive supply lines which is composed of column and row supply lines or word and bit lines, respectively. With this type of memory arrays with so-called crosspoint architecture, the memory cells are each positioned at the crosspoints of the electroconductive supply lines that are each connected with the memory cell via an upper electrode or top electrode and a lower electrode or bottom electrode. To perform a change of the information content in a particular memory cell at the addressed crosspoint or to recall the content of the memory cell, the corresponding word and bit lines are selected and impacted either with a write current or with a read current.

There are known different kinds of semiconductor memories, e.g. a RAM (Random Access Memory). A RAM memory device is a memory with optional access, i.e. data can be stored under a particular address and can be read out again under this address later. A particular kind of RAM semiconductor memories are DRAMs (Dynamic Random Access Memory) which comprise in general only one single, correspondingly controlled capacitive element per memory cell, e.g. a trench capacitor, with the capacitance of which one bit each can be stored as charge. The charge or the information stored, however, remains for a relatively short time only in a DRAM memory cell, so that a so-called “refresh” must be performed regularly, with the corresponding information content being written in the memory cell again, or being refreshed, respectively. In contrast to DRAMs, no “refresh” has to be performed in the case of SRAMs (Static Random Access Memory) as long as the supply voltage is present at the chip. In the case of non-volatile memory types such as EPROMs, EEPROMs, and flash memories, the stored data remain stored even when the supply voltage is switched off.

The presently common semiconductor memory technologies are based primarily on the principle of charge storage in materials produced by standard CMOS (complement metal oxide semiconductor) processes. The problem of the leaking currents existing with the DRAM memory concept, which result in a loss of charge or a loss of information, respectively, has so far been solved insufficiently only by the permanent refreshing of the stored charge, which results in a high energy consumption of the DRAM chip. The flash memory concept underlies the problem of write and read cycles limited by barrier layers, wherein no optimum solution has been found yet, either, for the high switching voltages and the slow read and write cycles. Moreover, long write times in the range of several ps to ms are required.

So-called CB memory cells or CBRAM memory cells (CB=Conductive Bridging) have also become known recently, in which digital information can be stored by a resistive switching process. A CB or CBRAM memory cell is adapted to be switched between different electric resistance values by means of bipolar electric pulsing. In a simple embodiment, such an element can be switched between a very high (e.g. in the GOhm range) and a distinctly lower resistance value (e.g. in the kOhm range) by applying short current or voltage pulses, wherein the switching rates may be below one microsecond.

The structure of conductive bridging memory cells (CB memory cells or CBRAM memory cells) or solid body electrolyte memory cells, respectively, consists substantially of an upper electrode or top electrode and a lower electrode or bottom electrode, and of a volume with electrochemically active material positioned therebetween, which may be doped with a metal, in particular with silver or e.g. copper. As an electrochemically active material for the ion conductor, materials such as GeₓSe₁₋ₓ, GeₓS₁₋ₓ, WOₓ, Cu—S, Cu—Se, or similar chalcogenide-containing compounds are generally used. As reactive materials for the reactive metal electrode, copper (CU) or in particular silver (Ag) are typically used. The CBRAM cell typically has an asymmetric structure, i.e. the electrode material 1 is different from the electrode material 2.

In the case of such CB memory cells, the above-mentioned switching process is on principle based on the fact that, by applying appropriate current or voltage pulses of particular intensity and duration at the electrodes in the active chalcogenide material positioned between the electrodes, metal-rich elements of so-called clusters continue to increase in their number and/or size in the chalcogenide material volume until the two electrodes are finally electroconductively bridged, i.e. electroconductively connected with each other, which corresponds to the electroconductive state of the CB memory cell.

By applying correspondingly inverse current or voltage pulses, this process can be reversed again, whereby the corresponding CB memory cell can be returned to a highly resistive state. This way, a switching between a state with a higher electroconductivity of the CB memory cell and a state with a lower electroconductivity of the CB memory cell is achieved. The electroconductivity of the CB memory cell can be assigned to a logic memory state (logic “1” or logic “0”). For detecting the state of the memory cell, the current is evaluated at an applied read voltage U_{read}, wherein U_{read}<U_{write} (write voltage).

So far, there have only been known results from the manufacturing of individual cells in vertical or co-planar geometry, which are, however, less suited for highly dense memories. It is therefore the general object of the present invention to provide a solid body electrolyte memory cell or CB memory cell, respectively, which is suited for competitive, commercial applications. To this end, CB memory cells have to be manufactured in an array with an integration that is as dense as possible, or with good scalability, respectively, making use of a technology that is as simple as possible and that yields reliable results.

As described above, it is possible with a solid body electrolyte memory cell to have metal ions diffuse in a controlled manner from the anode into the ion conductor by applying bipolar voltage pulses at the electrodes. In the simplest case, these metal ions are identical to the anode material, i.e. metal anode material is oxidized and is dissolved in the ion conductor on applying of a positive write voltage U_{write}>U_{read}. The ion diffusion may be controlled by the duration, the amplitude, and the polarity of the electric voltage externally impressed to the memory cell. On applying of a positive electric voltage U_{write} at the described solid body electrolyte memory cell, the metal cations diffuse, under the influence of the electric field applied externally via the electrodes of the CB memory cell, through the ion conductor in the direction of the cathode. As soon as a sufficient number of metal ions have diffused from the anode into the ion conductor, a lowly resistive metal bridge between the anode and the cathode can be formed, this causing the electric resistance of the memory cell to drop strongly since the highly resistive solid body electrolyte matrix is electrically short-circuited.

For such resistively switching CBRAM memories, only concepts for the manufacturing and programming of individual memory cells have been published so far. Since as many memory cells as possible are generally intended to be accommodated in a RAM memory device, one has been trying to manufacture same as simple as possible and on the narrowest space, i.e. to integrate them in a memory cell array or a memory cell field, and to scale them.

For the arrangement of a plurality of CBRAM memory cells in a memory cell array, the above-mentioned crosspoint architecture has, for instance, been suggested, in which the memory cells are controlled via a matrix of word and bit lines as well as a 1TnR arrangement in which a transistor, together with a number of switchable resistors, constitutes a memory cell. For both cases there has, however, not been known any integration concept so far.

### SUMMARY OF THE INVENTION

It is an object of the present invention to provide a concept for the integration of CBRAM memory cells with a 1T1R CBRAM architecture, wherein a transistor, together with a resistively switching solid body electrolyte element, constitutes a CBRAM memory cell. Another object consists in providing a method for manufacturing a memory cell array with a 1T1R CBRAM architecture which is as cheap as possible.

In accordance with the present invention, this object is solved by a memory cell field with the features indicated in claim 1, and by a method according to claim 8.

Advantageous embodiments of the invention are defined in the subclaims.

In accordance with an aspect of the present invention, the above-mentioned objects are solved by a memory cell field with an integrated arrangement of solid body electrolyte memory cells, and in particular of CBRAM solid body electrolyte memory cells with 1T1R architecture, wherein said memory cells each comprise a layer stack comprising at least a bottom and a top electroconductive, in particular metal, layer, and a layer of solid body electrolyte material or ion conductor material, respectively, positioned therebetween, and wherein each solid body electrolyte memory cells is adapted to be controlled via a word line, a bit line and a plate line by means of a selection transistor, wherein at least a number of solid body electrolyte memory cells in the memory cell field comprise a common plate electrode or are connected to a common plate line, respectively.

A substantial feature of the present invention consequently consists in that an electrode, in particular the top electrode or the plate line of a memory cell field, respectively, is designed as continuous plate or electrode, respectively, so that the memory cells of an array have a common electrode (plate line) or are connected with each other via a common electrode, respectively. Such a common electrode has the advantage that no expensive lithography processes with critical structures are necessary for their manufacturing. Thus, on the one hand, the structure of the inventive memory cell array is simplified and, on the other hand, the effort of the processes for their manufacturing is reduced and is thus cheaper.

In accordance with a further aspect of the present invention, the above-mentioned objects are solved by a method for manufacturing at least one memory cell field with an integrated arrangement of solid body electrolyte memory cells, and in particular of CBRAM solid body electrolyte memory cells, for generating a memory array with 1T1R architecture, wherein the method comprises at least the following steps:

depositing a bottom electrode material layer on a silicon substrate,

structuring the bottom electrode material layer for forming bottom circuit paths,

generating first electrodes for the solid body electrolyte memory cells,

generating a layer stack on the prestructured bottom electrode material layer by depositing a solid body electrolyte material or an ion conductor material, as well as a reactive metal, and

depositing a top electrode material layer for generating a second electrode to which a number of solid body electrolyte memory cells are commonly connected.

The present invention suggests a possibility of integration, whereby the manufacturing of a CB memory cell array or of a CBRAM memory cell array, respectively, can be integrated into a CMOS manufacturing method. To this end, different possibilities of realizing a CBRAM module with an integrated arrangement of 1T1R CBRAM memory cells in minimum structure size are indicated. With the integration approach according to the present invention it is possible to achieve a high memory cell density in the memory cell array, and to program, erase, and read individual CBRAM memory cells in the array independently of each other by a predetermined switching pulse scheme. By the present integration approach, the size of an individual cell may be reduced down to 6F², wherein F is the smallest lithographically resolvable lateral dimension (F=feature size). A particular advantage of the present invention consists in that, by the use of the so-called common plate architecture, the common top electrode or the plate line, respectively, of the CBRAM memory cells need not be structured individually for each CBRAM memory cell. Thus, a substantial simplification with respect to process technology is achieved vis-à-vis a standard integration approach which, for instance, provides for the structuring of a top electrode or plate line, respectively, for every single memory cell.

The principle of the present invention is based on the providing and the use of a common top electrode or plate line, respectively, for a plurality of CBRAM memory cells that are integrated or arranged in a memory cell array. To this end, this common top electrode is structured at the edge of the memory cell array or of the memory cell field, respectively, or at some other suitable position. The manufacturing of the common top electrode or plate line, respectively, is preferably performed by dry chemical or wet chemical methods, and is thus restricted in space.

For manufacturing the inventive memory cell array with integrated CBRAM memory cells, the CBRAM memory cell is placed on the so-called CC contact (“node contact”) or over the so-called CC contact, respectively, which is connected with the respective selection transistor in the silicon substrate via a co-called CA contact. In accordance with preferred embodiments of the inventive method there are suggested different integration approaches by which the active material (e.g. GeSe/Ag) of the solid body electrolyte memory cell is structured.

According to a preferred embodiment of the inventive method, the active solid body electrolyte material is filled into the back-etched CC contact and subsequently planarized. This process is preferably performed with the additional establishing of barrier layers so as to limit the diffusion region of the solid body electrolyte material.

To this end, the finished and planarized contact is, for instance, etched back by wet chemical etching by a particular degree so as to create the space required for the memory resistor. In addition, the memory cell array or the cell field, respectively, may be covered relative to the periphery by means of an uncritical lithography step. Subsequently, the ion conductor material (e.g. GeSe) and the reactive metal (e.g. Ag) may be deposited. Then, both the ion conductor material and the reactive metal are planarized by means of chemical mechanical polishing (CMP).

Alternatively, it is possible to first deposit and planarize the ion conductor material, and to subsequently commonly deposit planarly reactive metal and the plate electrode. This way it can be prevented that the reactive metal (Ag) is structured. At any rate, however, the plate electrode is structured after its deposition with a likewise uncritical lithography step at the edges of the memory cell array or the cell field, respectively, or at some other suitable position.

In accordance with a second preferred embodiment of the inventive method, a diffusion barrier, for instance, of SiN is applied conformely after the back-etching of the plug (and TiN liner), and subsequently the contact to the plug is re-established by means of anisotropic etching. This prevents a possible diffusing out of the active materials such as silver ions.

In accordance with a third preferred embodiment of the inventive method, the necessary planarizing of the active material may also be performed without the use of a CMP tool. In analogy to the above-described procedure, the plug (with the TiN liner) is etched back, and subsequently the ion conductor material is deposited. When depositing the ion conductor material, care has to be taken not to completely fill the opening provided, but to fill it only partially. Subsequently, the reactive metal (Ag) is deposited and the chalcogenide layer created is doped, wherein, again, a complete via filling is avoided.

Subsequently, a nitride sacrifice layer and a thick oxide sacrifice layer are deposited to balance the remaining topography. This is then chemically mechanically polished in a standard process with a CMP tool down to the nitride layer and planarized, and the SiN of the diffusion barrier is etched at the exposed positions. Subsequently, the active material can be structured in the vias with a wet etching step, and finally the now superfluous sacrifice layers can be removed again. Then, the plate electrode can be deposited and structured.

Similar to the above-described third preferred embodiment is a fourth preferred embodiment of the inventive method, wherein an additional diffusion barrier, for instance, of SiN, is also introduced, and the contact to the plug is made by an anisotropic back-etching step.

A substantial aspect with the above-described embodiments of the inventive method consists in that, as a result, a plurality of memory cells are electrically connected to a common top electrode, the so-called plate line (PL).

In accordance with the present invention, the plate line may, during the operation of the CBRAM memory cells, in the simplest case be kept on a constant potential level, which has been explained in conjunction with FIG. 1 with respect to the pulse triggering of the bit line and the word line of a resistively switching solid body electrolyte memory cell. The result of this is, in addition to a simple connection of the memory cells, also the advantage of a minimal mutual influencing of the respective memory cells.

### BRIEF DESCRIPTION OF THE DRAWINGS

In the following, the invention will be explained in more detail by means of preferred embodiments with reference to the enclosed drawings.

FIG. 1 shows two diagrams for pulse triggering of the bit line and of the word line of a resistively switching solid body electrolyte memory cell, e.g. a CBRAM memory cell;

FIG. 2 shows an arrangement or an electric circuit, respectively, of solid body electrolyte memory cells in 1T1R CBRAM architecture based on a memory cell field with 1T1R CBRAM memory cells according to a preferred embodiment of the present invention;

FIG. 3 shows a schematic sectional view through a memory cell field with 1T1R CBRAM architecture according to a first preferred embodiment of the present invention;

FIG. 4 shows a schematic sectional view through a memory cell field with 1T1R CBRAM architecture according to a first preferred embodiment of the present invention illustrated in FIG. 3, wherein the plane of the sectional view of FIG. 4 extends along the line A-A plotted in FIG. 3;

FIG. 5 shows a schematic sectional view through a memory cell field with 1T1R CBRAM architecture according to a second preferred embodiment of the present invention;

FIG. 6 shows a schematic sectional view through a memory cell field with 1T1R CBRAM memory cells according to a third preferred embodiment of the present invention;

FIGS. 7 and 8 show schematic representations of individual process steps of a preferred embodiment of the inventive method for manufacturing a memory cell field with 1T1R CBRAM architecture according to the embodiment of the present invention illustrated in FIG. 6; and

FIG. 9 shows a schematic sectional view through a memory cell field with 1T1R CBRAM architecture according to a third preferred embodiment of the present invention.

### DETAILED DESCRIPTION OF THE INVENTION

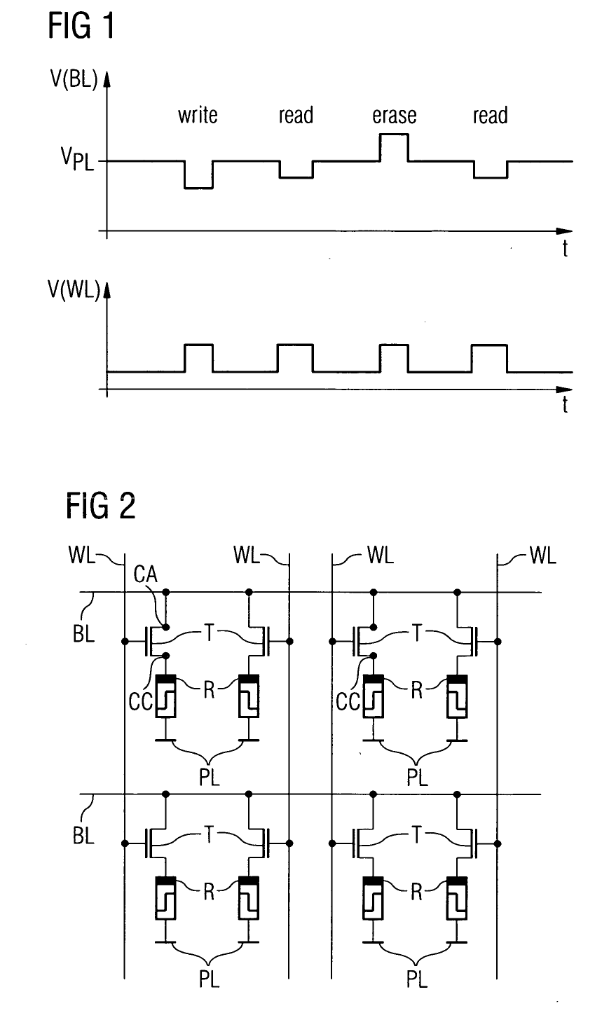

FIG. 1 shows respective diagrams for pulse triggering in the form of voltage pulses at the bit line V(BL) and at the word line V(WL) of a resistively switching solid body electrolyte memory cell. The diagrams each show a time sequence of a write pulse “write”, a read pulse “read”, an erase pulse “erase”, and a further read pulse “read” at the electrodes of the solid body electrolyte memory cell.

As described above, metal ions are diffused in a controlled manner from the anode into the ion conductor of the solid body electrolyte memory cell by applying bipolar voltage pulses at the electrodes of the solid body electrolyte memory cell. On applying a positive electric write voltage U_{write}>U_{read} at the electrodes of the solid body electrolyte memory cell, the metal cations diffuse from the anode under the influence of the external electric field through the ion conductor in the direction of the cathode, and dissolve in the ion conductor. The extent of the ion diffusion is controlled by the duration, the amplitude, and the polarity of the electric voltage impressed externally in the CB memory cell.

On applying an inverse electric erase voltage Uₑᵣₐₛₑ at the electrodes of the solid body electrolyte memory cell, the metal cations diffuse from the ion conductor back to the anode, whereby the density of the metal ions in the ion conductor decreases. For reading the CB memory cell, lower pulse intensities or voltages U_{read} are used so as not to change the state of the memory cell. For measuring the voltage pulses, a medium plate voltage VPL can always be assumed since, for the described operations in the CBRAM memory cell, only the corresponding voltage relation between the bit line and the word line has to exist. In accordance with the invention, the plate voltage VPL may remain constant since the voltage relations at the word and bit lines are authoritative for the different modes of operation of the CBRAM memory cell.

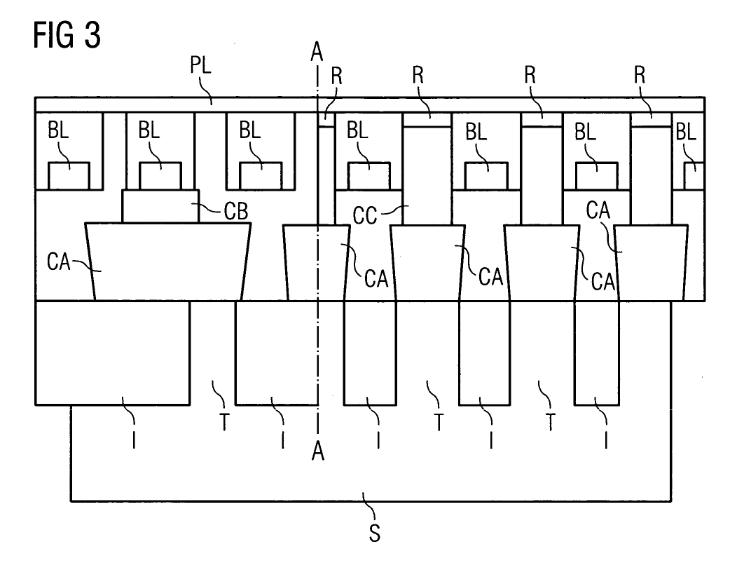

FIG. 2 shows an arrangement of solid body electrolyte memory cells in an electric circuit with 1T1R CBRAM architecture, as it may be the basis for a memory cell field with 1T1R CBRAM memory cells according to a preferred embodiment of the present invention. The memory cell field comprises electric supply lines that are oriented orthogonally to each other in a matrix of word lines WL and bit lines BL. In accordance with the 1T1R architecture, a resistor or a resistively switching solid body electrolyte memory cell R, respectively, each is connected in series with a selection transistor T, wherein the transistor T is connected with the bit line BL at the side opposite to the resistor and with the adjacent word line WL at its gate.

At the side opposite to the transistor, the resistively switching solid body electrolyte memory cell or CBRAM memory cell R is connected to a plate line. The plate lines extend in a different plane than the word lines WL and the bit lines BL and are therefore not illustrated in FIG. 2. According to one aspect of the present invention, the plate lines PL of the CBRAM memory cells R are connected with one another, i.e. all CBRAM memory cells R of a memory cell field, or the CBRAM memory cells from a particular region of the memory cells field, respectively, are connected to a common plate line.

Between the bit line BL and the transistor T there is positioned a CA contact, and between the transistor T and the solid body electrolyte memory cell or CBRAM memory cell R there is positioned a CC contact, preferably of tungsten (W), which will be described in more detail in the following. With this 1T1R CBRAM architecture, only one transistor element each is needed for controlling a CBRAM memory cell in an inventive memory cell field.

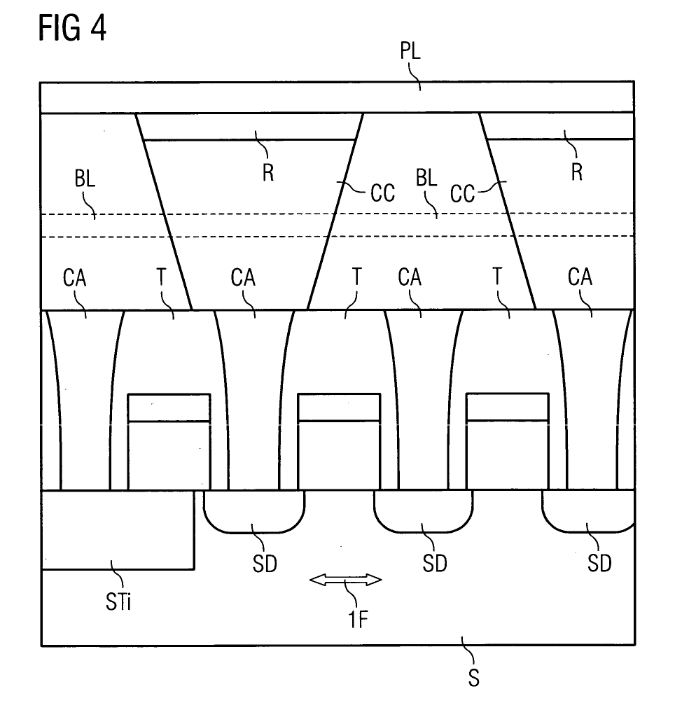

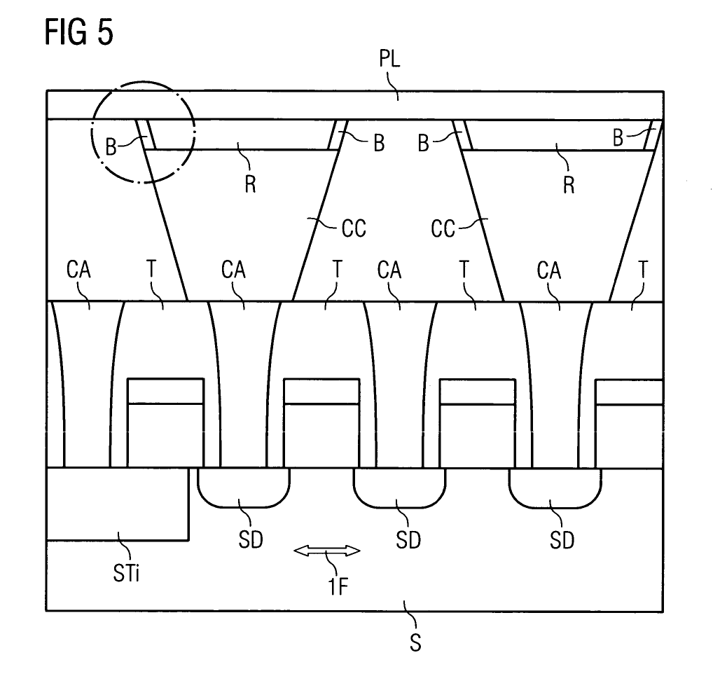

FIG. 3 shows a schematic sectional view through a memory cell field with 1T1R architecture according to a first preferred embodiment of the present invention. FIG. 3 includes a line A-A which constitutes the section plane of FIG. 4. At the left of the line A-A there is represented a sectional view through a CB contact while on the right side of the line A-A there is represented a sectional view through a CC contact (“node contact”).

The inventive memory cell field is built up on a silicon substrate S in which transistors or selection transistors T, respectively, are structured which are each separated from one another by isolations I. The transistors are each contacted via a so-called CA contact CA on which there is positioned a so-called CB contact connecting the CA contact and thus the selection transistor T with a bit line BL. In another plane of the inventive memory cell field which is represented at the right side of the line A-A, a selection transistor T is connected with the active material of a resistively switching solid body electrolyte memory cell R via the CA contact and the CC contact, this resulting in the 1T1R architecture of the memory cell field.

At the side opposite to the CC contact, the solid body electrolyte memory cell is connected with a plate line PL that is formed as a continuous electrode plate. This way, the solid body electrolyte memory cells of the memory cell field, or a number of memory cells of a subarray of the memory cell field, are connected with each other via a common plate line or via a common plate electrode, respectively. The use of a common plate electrode results in an inventive memory cell field with a simple structure, for the manufacturing of which lithography processes with little effort and absent of critical structures are required.

FIG. 4 shows a schematic sectional view through a memory cell field with 1T1R CBRAM architecture according to a first preferred embodiment of the invention illustrated in FIG. 3, wherein the plane of the sectional view of FIG. 4 extends along the line A-A plotted in FIG. 3. As with the view represented in FIG. 3, the inventive memory cell field is structured on a silicon substrate S in which transistors or selection transistors T are structured, the source/drain regions SD of which are isolated from each other, for instance, by a shallow trench isolation STI. The double arrow designated with F (F=feature size) indicates the smallest lithographically resolvable lateral dimension or structure size, respectively, that can be achieved by the lithography used.

The selection transistors T are each contacted via a so-called CA contact CA which is in turn connected with the active material R of the solid body electrolyte memory cell by a CC contact. Since the bit line BL is positioned in a different plane than the paper plane of FIG. 4, the bit line BL is indicated in dashed lines. The CC contact thus constitutes the lower electrode or bottom electrode of the solid body electrolyte memory cell. Above the region with the active material R of the solid body electrolyte memory cell there is arranged the plate line PL that extends as a continuous electrode plate over a number of solid body electrolyte memory cells of the memory cell field. The plate line PL thus constitutes the common upper electrode or the common top electrode, respectively, for a number of solid body electrolyte memory cells.

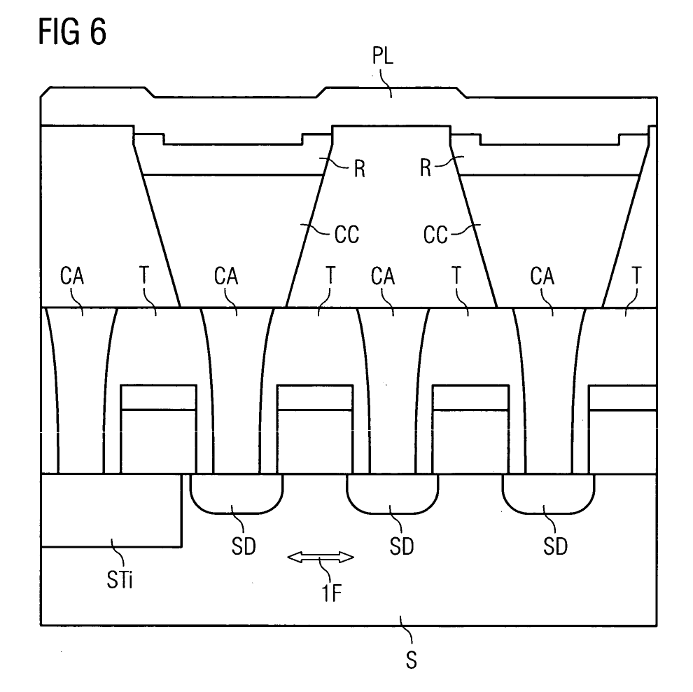

FIG. 5 shows a schematic sectional view through a memory cell field with 1T1R CBRAM architecture according to a second preferred embodiment of the present invention. The embodiment of the inventive memory cell field illustrated in FIG. 5 corresponds in many features to the embodiment illustrated in FIG. 4, so that the following description restricts itself to the differing features.

The active material of the solid body electrolyte memory cell may contain silver-bearing material that has a high mobility in SiO₂, so that is adapted to diffuse out of the region with the active material R and to spread in an uncontrolled manner in the memory cell field. By silver impurities the characteristic curves of the selection transistors T and the electric behavior of other components in the silicon substrate S may be modified, and thus the function of the memory cell field may be impaired as a whole.

To prevent an impairment of the functionability of the solid body electrolyte memory cell by diffusing substances from the region with the active material R, it is suggested with a memory cell field according to the second preferred embodiment of the present invention to laterally restrict the region with the active material R of the solid body electrolyte memory cell by means of barrier layers B. Thus, a diffusing out of the silver material, of the silver-bearing material, or of other substances from the region with the active material R can be prevented so as to guarantee a best reliable responding behavior of the selection transistors T with defined threshold values.

To this end, the edges of the region with the active material R of the solid body electrolyte memory cell are provided with a barrier layer B that extends from the bottom electrode or the CC contact CC, respectively, to the upper electrode or the plate line PL, respectively, of the solid body electrolyte memory cell. The barrier layer B may be manufactured of a nitride compound such as silicon nitride, aluminum nitride, or another isolating material.

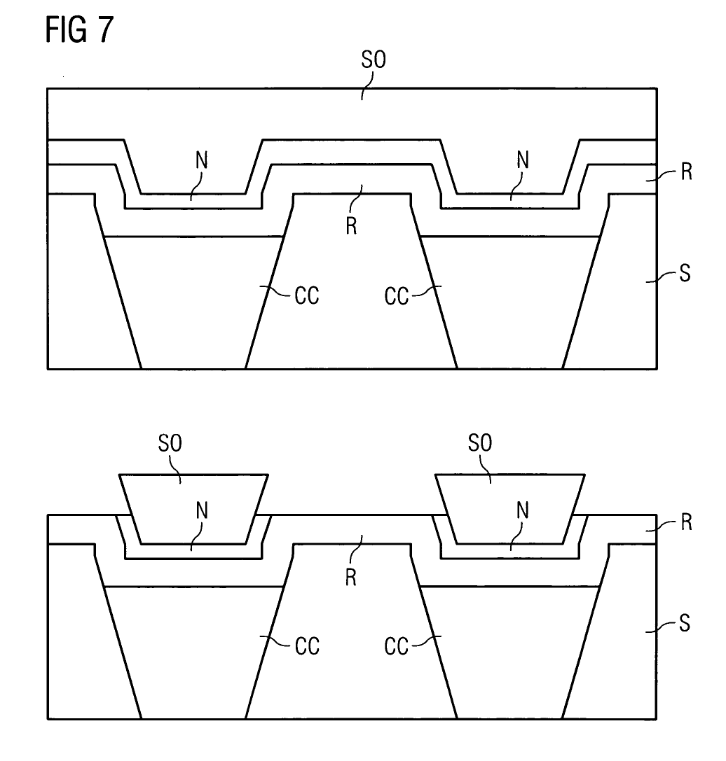

FIG. 6 shows a schematic sectional view through a memory cell field with 1T1R CBRAM memory cells according to a third preferred embodiment of the present invention. The embodiment of the inventive memory cell field illustrated in FIG. 6 corresponds in most features to the embodiments illustrated in FIG. 4 or in FIG. 5, so that the following description restricts itself to the deviating features. As may be seen from FIG. 6, the region with the active material R of the solid body electrolyte memory cell is designed in the form of a well, so that the region with the active material or chalcogenide material R, respectively, comprises a recess at the upper face that is in communication with the plate line PL. This way, the region with the active material R can be formed with an exactly defined strength, this improving the determinability of the characteristic curves and of the threshold voltages of the solid body electrolyte memory cell.

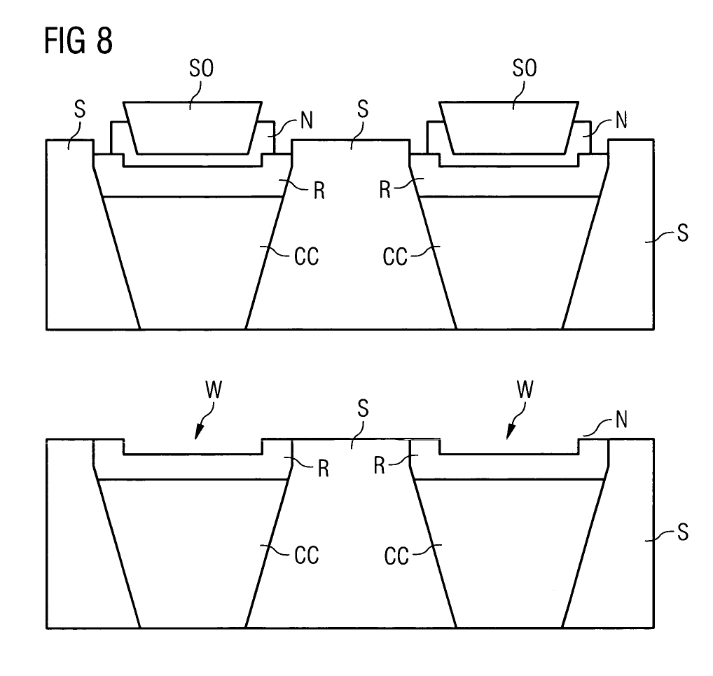

FIGS. 7 and 8 show a schematic representation of individual process steps of a preferred embodiment of the inventive method for manufacturing a memory cell field with 1T1R CBRAM architecture according to the embodiment of the present invention illustrated in FIG. 6. For performing the inventive method for manufacturing a memory cell field with an integrated arrangement of solid body electrolyte memory cells, and in particular of 1T1R CBRAM memory cells, a layer stack is first of all generated which comprises a number of different material layers, as is illustrated in the top portion of FIG. 7.

The bottom layer consists of a silicon substrate S that has been preprocessed in a suitable manner. In this silicon substrate S, the structures for the bottom electrodes or CC contacts or also so-called plugs CC for the solid body electrolyte memory cells are incorporated by suitable lithographic processes and etching processes, and are preferably filled with tungsten and planarized such that the desired tungsten plugs are generated. An active material or chalcogenide material R with a defined thickness for the CB memory cell is deposited on the CC contacts CC and doped with silver. Thereupon, a nitride layer N is deposited which serves in subsequent process steps as a protective layer for the layer with the active material R, and as an etch stop layer. Finally, a layer of silicon oxide SO is deposited over the nitride layer N.

The following method step is illustrated in the bottom portion of FIG. 7, in which the silicon oxide layer SO is, for instance, by a dry or wet chemical process, etched away down to the nitride layer N and is planarized. The nitride layer N may be used as an etch stop layer. After this process, a kind of protective cap or a dummy oxide SO, respectively, of silicon oxide remains left in the region above the active material R over the nitride layer N.

The following process step is illustrated in the top portion of FIG. 8, in which a vertically acting erosion process is, for instance, performed by sputtering and mainly erodes the chalcogenide material R and leaves the silicon oxide SO substantially unchanged, so that the nitride layer N below the dummy oxide SO also remains left. The barrier B acts as an isolator since it preferably only consists of Si₃N₄ or of AlN. In this preferably wet chemical partial chalcogenide etching process the chalcogenide material R is therefore removed only partially at the lateral edges in the region between the protective cap SO of silicon oxide and the silicon substrate S.

In the subsequent process step that is illustrated in the bottom portion of FIG. 8, the protective cap or the dummy oxide SO, respectively, of silicon oxide is removed completely together with the remaining nitride layer N by a suitable etching method or by a plurality of suitable method steps, respectively, so that a well W with defined strength is formed in the region with the active chalcogenide material R. Subsequently, a continuous layer of metal electrode material is deposited, so that a continuous upper electrode or a common top electrode, respectively, or a common plate line can be formed. This way, the structure of the inventive memory cell field illustrated in FIG. 6 can be generated, in which the region with the active material or the chalcogenide material R, respectively, has a defined strength.

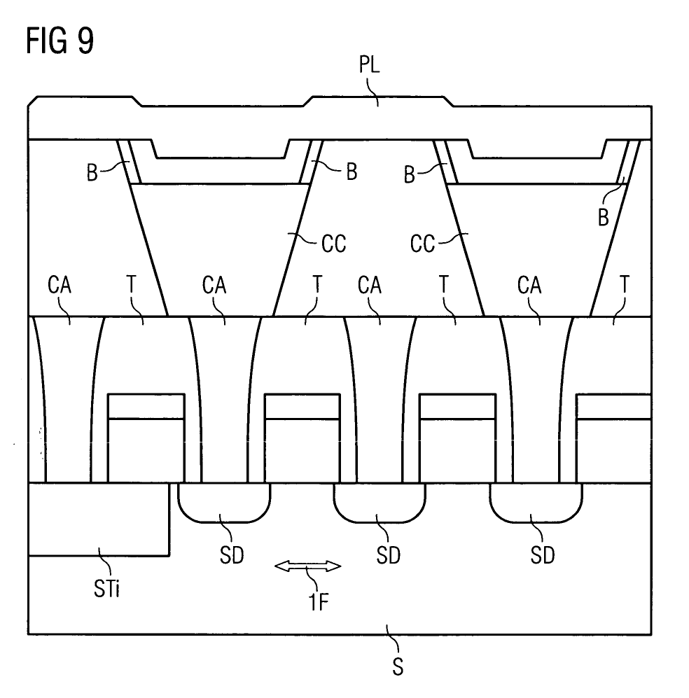

FIG. 9 shows a schematic sectional view through a memory cell field with 1T1R CBRAM architecture according to a third preferred embodiment of the present invention. The embodiment of the inventive memory cell field illustrated in FIG. 9 corresponds in most features to the embodiment illustrated in FIG. 6, so that the following description concentrates on the deviating features. Also with the embodiment illustrated in FIG. 9 is the region with the active material R of the solid body electrolyte memory cell designed in the form of a well W, so that the region with the active material or chalcogenide material R, respectively, comprises a recess at the upper area that is in communication with the plate line PL. Additionally, the region with the active material R is limited laterally by barrier layers B so as to prevent a lateral diffusing out of substances from the region with the active material R.

Such a structure may, for instance be generated in that the processes described by means of FIGS. 7 and 8 are performed, with the difference that the process step for removing the active chalcogenide material R at the lateral edges in the region between the protective cap SO of silicon oxide and the silicon substrate S (FIG. 8 top) is performed correspondingly longer, so that the edges of the active material R are completely eroded. After the back-etching of the plug (and the TiN liner), the generated gaps could then, for instance, be filled with SiN, and subsequently the contact to the plug could be re-established by anisotropic etching.

### LIST OF REFERENCE SIGNS

AA section plane of FIG. 4 in FIG. 3
CA CA contact
CB CB contact
CC CC contact or “node contact”
F smallest lithographically resolvable lateral dimension
I isolations between the selection transistors
N nitride layer
S silicon substrate
SD source/drain region of the transistor
SO silicon oxide layer or dummy oxide
STI shallow trench isolation
T selection transistor
R CBRAM memory cell or solid body electrolyte material
W well in the layer with solid body electrolyte material
WL word line
BL bit line
PL plate line

What is claimed is:

1. A memory cell field with an integrated arrangement of solid body electrolyte memory cells, and in particular of CBRAM solid body electrolyte memory cells with 1T1R architecture, wherein the solid body electrolyte memory cells each comprise a layer stack (CC, R, PL) that comprises at least a bottom (CC) and a top electroconductive, in particular metal layer (PL) and a layer (R) of solid body electrolyte material or ion conductor material, respectively, positioned therebetween, and wherein each solid body electrolyte memory cell can be controlled via a word line (WL), a bit line (BL), and a plate line (PL) by means of a selection transistor (T),
wherein at least a number of solid body electrolyte memory cells in the memory cell field have a common plate electrode (PL) or are connected to a common plate line (PL), respectively.

2. The memory cell field according to claim 1, wherein the plate lines or plate electrodes (PL) of a number of solid body electrolyte memory cells of the memory cell field are electrically connected with each other, for instance, via a common electrode plate of an electroconductive, in particular metal material.

3. The memory cell field according to claim 1, wherein, of the memory cell field, e.g. with a size of 1024×1024 memory cells, only one or a plurality of subarrays, for instance, with a size of 64×64 cells, comprise a common plate electrode (PL) or are connected to a common plate line (PL), respectively.

4. The memory cell field according to claim 1, wherein those solid body electrolyte memory cells in the memory cell field that are positioned along a bit line or along a word line (WL), respectively, have a common plate electrode (PL) or are connected to a common plate line (PL), respectively.

5. The memory cell field according to claim 1, wherein the top or the bottom electroconductive, in particular metal layer of the layer stack (CC, R, PL) constitutes the common plate line (PL) or the common plate electrode (PL), respectively.

6. The memory cell field according to claim 1, wherein at least parts of the layer stack (CC, R, PL) are encapsulated by a diffusion barrier (B) that preferably comprises a dielectric.

7. The memory cell field according to claim 6, wherein the dielectric or the diffusion barrier (B), respectively, is manufactured of a nitride, in particular of Al—N or Si—N.

8. A method for manufacturing at least one memory cell field with an integrated arrangement of solid body electrolyte memory cells, and in particular of CBRAM solid body electrolyte memory cells, for generating a memory array with 1T1R architecture, wherein the method comprises at least the following steps:
depositing a bottom electrode material layer (CC) on a silicon substrate (S),
structuring the bottom electrode material layer for forming bottom electrode paths,
generating first electrodes (CC) for the solid body electrolyte memory cells,
generating a layer stack on the prestructured bottom electrode material layer by depositing
a solid body electrolyte material or an ion conductor material (R), respectively, and
a reactive metal for doping the ion conductor material (R), and
structuring regions (R) with solid body electrolyte material or ion conductor material, respectively, for the solid body electrolyte memory cells,
depositing a top electrode material layer for generating a second electrode (PL) to which a number of solid body electrolyte memory cells are commonly connected.

9. The method according to claim 8, wherein, by the depositing and structuring of the bottom electrode material layer (CC), bottom electrodes of the memory cell field, and, by the depositing of the top electrode material layer, a common plate line or plate electrode (PL), respectively, for a number of solid body electrolyte memory cells or for all solid body electrolyte memory cells, respectively, in the memory cell field are formed.

10. The method according to claim 8, wherein, by the depositing and structuring of the bottom electrode material layer (CA, CC), contacts to the selection transistor of the memory cell field, and, by the depositing of the top electrode material layer, a common plate line (PL) for a number of solid body electrolyte memory cells or for all solid body electrolyte memory cells, respectively, in the memory cell field are formed.

11. The method according to claim 8, wherein the depositing of the top electrode material (PL), of the bottom electrode material (CC), of the solid body electrolyte material, and/or of the reactive metal (R) is performed by depositing at least one layer of the corresponding material.

12. The method according to claim 8, wherein the method steps for the structuring of material layers (S, CA, CB, CC, R, PL) are each performed with a suitable anisotropic etching method, e.g. by means of an etching method with reactive ions (RIE=Reactive Ion Etching).

13. The method according to claim 8, wherein the regions (R) with solid body electrolyte material or ion conductor material, respectively, for the solid body electrolyte memory cells are provided with lateral diffusion barriers (B) that prevent a diffusing out of substances from the region (B).

14. The method according to claim 13, wherein the entire layer stack (CC, R, PL) or only parts of the layer stack (CC, R, PL) are provided with diffusion barriers (B).

15. The method according to claim 14, wherein, for generating an ion conductor material layer (R) with diffusion barriers (B),
a nitride sacrifice layer (N) and subsequently an oxide sacrifice layer (S) are deposited,
the nitride sacrifice layer (N) and the oxide sacrifice layer (S) are, preferably by chemical mechanical polishing, chemically mechanically polished down to the nitride sacrifice layer (N) and planarized, and the material of the diffusion barrier (B) is etched at the exposed positions,
the active material (R) is structured in the generated vias preferably with a wet etching step,
the nitride sacrifice layer (N) and the oxide sacrifice layer (S) are removed again, and subsequently
the plate electrode (PL) is deposited and structured.

16. The method according to claim 8, wherein electrochemically active chalcogenide material, preferably of germanium and/or silicon, selenium and/or sulphur, silver and/or copper, e.g. in a GeSe, GeS, SiSe, SiS, Ge—Si—Se, Ge—Si—S, Ge—Si—Se—S, Ag compound and/or Cu compound, is used as solid body electrolyte material or as ion conductor material (R), respectively.

17. The method according to claim 8, wherein silver or copper is used as reactive metal for doping the active material (R) of the solid body electrolyte memory cell.

18. The method according to claim 8, wherein preferably metal such as tungsten or aluminum is used for the top electrode material layer (PL).

19. The method according to claim 8, wherein first of all the ion conductor material (R) is deposited and planarized, and subsequently reactive metal is deposited together with the material for the top electrode layer (PL).

20. The method according to claim 8, wherein, prior to the deposition of the ion conductor material (R), openings for the regions (R) with the ion conductor material are generated, which are only partially filled during the deposition of the ion conductor material (R) and the deposition of the reactive metal.

21. The method according to claim 8, wherein the contact of the diffusion barrier (B) to the bottom electrode (CC) is made by an anisotropic back-etching step.

22. The method according to claim 8, wherein the diffusion barrier (B) is made of SIN, or AlN, or Al—Si—N.

23. A system with a memory device comprising at least one solid body electrolyte memory cell manufactured according to claim 8.
